(19) United States
(12) Patent Application Publication
(10) Pub. No.: US 2025/0309839 A1
(43) Pub. Date: Oct. 2, 2025

(54) PULSED POWER AMPLIFIER SYSTEM AND METHOD

(71) Applicant: ZincFive, Inc., Tualatin, OR (US)

(72) Inventor: Michael G. Klasen, Lake Oswego, OR (US)

(21) Appl. No.: 19/085,997

(22) Filed: Mar. 20, 2025

Related U.S. Application Data
(60) Provisional application No. 63/573,362, filed on Apr. 2, 2024.

(51) Int. Cl. H03F 3/217; H03F 1/02

(52) U.S. Cl. CPC H03F 3/2171; H03F 1/0222; H03F 2203/21184

(57) ABSTRACT

Methods and systems for providing pulse power amplification for an electric load are described. In one example, nickel/zinc battery cells are selectively coupled to a graphic processing unit (GPU) during times of higher power consumption that may be driven by larger computational loads. The nickel/zinc battery cells may supply large amounts of direct current (DC) power to the GPU without having to convert to a voltage level that meets GPU specifications.

### CROSS REFERENCE TO RELATED APPLICATION

The present application claims priority to U.S. Provisional Application No. 63/573,362, entitled “PULSED POWER AMPLIFIER SYSTEM AND METHOD”, and filed on Apr. 2, 2024. The entire contents of the above-listed application(s) are hereby incorporated by reference for all purposes.

### TECHNICAL FIELD

The present disclosure relates to supplying electric power to a load that exhibits large variations in electric power consumption.

### BACKGROUND AND SUMMARY

Hardware acceleration of artificial intelligence (AI) data processing with graphic processing units (GPUs) may result in intermittent and often brief increases in GPU electric power consumption that may be referred to as GPU load pulses. GPU load pulses are difficult to avoid by applying software-enabled task sharing between heavily loaded and lightly loaded GPUs because hardware acceleration includes a GPU computational task to be loaded and processed to completion with power consumption variability being a result of processing and not as an easily controlled variable such as central processing unit (CPU) data processing. This type of power boosting increases GPU performance, but it is time constrained due to thermal and electric power constraints. The thermal and electric power constraints may contribute to intermittency and brief durations of electric load pulses that may be generated by a GPU.

Issues that may be caused by GPU load pulses include financial expense of compensation for the electric load pulses, size of power supply, power supply efficiency, thermal management, and underutilization of a power supply unit (PSU) infrastructure. PSU infrastructure includes financial expense and losses (e.g., heat losses) that may be associated with power generation, transmission, distribution, conversion, and delivery to the GPU at specified voltages.

A way to address GPU load pulse issues is to oversize the GPU PSU by as much as 2-3 times the rated thermal design power (TDP) of the GPU. However, oversizing the GPU PSU does not address the issue of insufficient utility or grid power supply to power more powerful GPU PSUs. What is desired is a low-cost solution that is physically located close to the GPU that may support increased load pulse frequency, duration, and power without a proportional increase in the utility or grid power utilized by the AI processing center.

GPU network communications and liquid cooling calls for synchronized GPUs used for training purposes to be in proximity to reduce control latency and cooling costs. For this reason, AI datacenter designers strive to relocate non-GPU hardware like power supply units from inside the server cabinets beside GPUs and other computing hardware to remote location(s) that do not interfere with GPU operations. Power supplies, pulse load mitigation hardware, and backup power (e.g., a DC UPS) energy storage devices like batteries and supercapacitors are a main target for relocation.

Remote location and/or distribution of PSUs that convert utility alternating current (AC) power to the GPU cabinet 50 V DC power bus power is a problem because of the direct current (DC) resistance losses caused by large currents in low voltage, high power systems.

480 VAC class power distribution within datacenters requires transmission of widely variable base load and pulse load power from the AC utility to GPU cabinets causes particular to AC power distribution challenges such as the desire to maintain reactive AC power factor and THD limits when the GPU power requirements vary significantly on a millisecond or less time scale. Data center AC power distribution also introduces the wiring complexity of managing three or four conductor for three phase AC.

For the above reasons, higher voltage DC power transmission lines in the range of 400-800 V DC are desired to transmit power from remotely located PSU resources to GPU compute cabinets. The pulse power amplifier accommodates higher voltage DC power applications by adding additional serial pulse power battery trays as shown in FIG. 9 of the present specification.

The pulse power amplifier (PPA) design requires a trigger signal to enable timely GPU pulse load mitigation. The simplest form of trigger monitors the GPU cabinet 50 V DC power bus and connects battery string resources when bus voltage droops to a low voltage threshold and disconnects battery string resources when the bus voltage rises to a high voltage threshold. Problems with this simple PPA trigger control mechanism include: (1) inability to measure GPU pulse power loads because the AC to DC PSU in parallel to the PPA device adjusts its output power on a microsecond response time basis which effectively masts GPU DC load power fluctuations on the DC power bus that would otherwise be associated with GPU pulse loads, (2) inability to detect small DC bus fluctuations due to noise on the DC bus, (3) inability to use DC bus voltage as a trigger control mechanism based on actual GPU pulse load demand when AC power to the AC to DC PSU is not available. In this case, there is no mechanism to detect GPU loads and avoid the potential of battery connection and disconnection operations from causing greater than acceptable DC bus voltage fluctuations.

An additional PPA signal control mechanism is a direct load current sense output signal from the GPU DC power supply input or equivalent GPU cabinet power management control system. This direct GPU load current sensor function is, as of the time of writing this note, not available from GPU OEMs and/or has not been provisioned for in existing GPU and GPU cabinet designs. The PPA can use this type of control signal to detect and mitigate GPU pulse loads.

An additional current sense PPA trigger control mechanism that is now available comes from the PSU for main use for parallel PSU current sharing equalization. This same signal, when properly scaled for the number of PSU units in any specific power supply configuration and interpreted according to the PSU DC output load to AC input load transfer function, can provide the <1 millisecond reaction time required for PPA to detect and mitigate GPU pulse loads.

The PSU input AC waveform provides the information required for an additional current sense PPA trigger control mechanism. This novel method relies upon knowledge of the PSU DC current load output to AC current load input transfer function which can be acquired by knowledge of PSU specifications, dynamic in-situ PSU characterization, or a combination of both knowledge sources. An example of the PSU DC load output to AC load input transfer function is the PSU smoothing of DC loads spikes over time while maintaining energy conservation. For example, a 10 millisecond, 1,000 Joule DC pulse load may be transformed by the PSU into a 100 millisecond, 1000 Joule AC pulse load through use of PSU capacitor energy storage located internally to the PSU.

The PPA trigger sense function can therefore use an AC current input waveform current measurement change to detect the existence of a DC pulse load being applied to the DC output of the PSU to trigger mitigating battery string current injections to the GPU DC power bus. Three conditions are required for this AC input sense PPA trigger control mechanism to work:
(1) The DC to AC current load propagation delay is to be fast enough in comparison with the AC power cycle to facilitate the type of “fast follower” GPU pulse load sense and mitigation method described here. This condition is met by most GPU cabinet PSUs which have propagation delays in the microseconds range.
(2) The PPA battery response time after an AC pulse load trigger input signal is to be fast enough to facilitate the “fast follower” function. PPA proof of concept test results show battery response times ≤100 psec, which is considered more than fast enough to facilitate a fast follower AC load current mitigation control mechanism.
(3) There may be a sufficiently close relationship in both time and current sense magnitude between AC load detection and DC PPA mitigation resource allocation. The fast follower AC current PPA trigger mechanism will not work if AC load detection is done in at location with sufficient delay to disable the fast trigger sense PPA function. The AC input sense method will also not work if there is not a sufficiently close to one-to-one relationship between DC load mitigation power and AC load power detection. For example, it is not possible to use a single aggregated AC load sensor for four GPU cabinets when DC load mitigation is executed at a single GPU cabinet level.

The inventor herein has recognized the aforementioned challenges and desires and has developed a pulse power amplifier, comprising: a battery cell string; a pulse power amplifier control device electrically coupled to the battery cell string; and a controller configured to control electric power flow through the pulse power amplifier control device in response to a voltage of an electric load or an amount of electric power consumed by the electric load.

The pulse power amplifier is applicable for DC pulse load mitigation when used in parallel with AC power supply system PSUs but is not able to function as a standalone device to provide regulated DC power when PSU AC power input is not available. For this purpose, one or more bi-directional DC/DC converters are used in series or in parallel with the pulse power amplifier power path. The pulse power amplifier may be desired to detect and mitigate pulse disruption conditions that may strain AC power through the delivery of high-power DC pulses time to offset the disruption to maintain steady AC conditions.

By arranging battery cells in string and controlling power flow out of the battery cell string via a controller in response to a voltage of an electric load and/or a power consumption rate of the electric load, it may be possible to provide the technical result of meeting power specifications of the electric load without the financial expense and other technical disadvantages of having to oversize a power supply.

The pulsed power amplifier system that is described herein may provide several advantages. In particular, the pulsed power amplifier system may have significant financial expense advantages over power systems that are oversized or that rely on capacitors (e.g., lower financial expense per watt of GPU pulse load compensation). Further, the approach permits battery strings that have different actual total numbers of battery cells to be electrically coupled in parallel to supply electric power to a load. This may permit battery strings with degraded battery cells to remain active. Additionally, the approach may be implemented with a simple architecture and simple controller or with a more sophisticated controller depending on system objectives. The PPA architecture allows for easy scaling of battery string cell count and battery string count for voltage and power requirements. The approach may mitigate utility or grid power increases and higher voltage alternating current (AC) to GPU 0.8-1.1 VDC pulse load compensation. Further, the approach may reduce carbon footprint of utility or grid power generation and GPU power conversion hardware.

It may be understood that the summary above is provided to introduce in simplified form a selection of concepts that are further described in the detailed description. It is not meant to identify key features of the claimed subject matter, the scope of which is defined by the claims that follow the detailed description. Furthermore, the claimed subject matter is not constrained to implementations that solve any disadvantages noted above or in any part of this disclosure.

### BRIEF DESCRIPTION OF THE FIGURES

FIG. 1 is a schematic of a first pulse power amplifier.

FIG. 2 shows an example operating sequence for the first pulse power amplifier.

FIG. 3 shows a flowchart of a method for controlling the first pulse power amplifier.

FIG. 4 is a schematic of a second pulse power amplifier.

FIG. 5 is an example operating sequence for the second pulse power amplifier.

FIGS. 6-8 shows a flowchart of a method for controlling the second pulse power amplifier.

FIG. 9 shows a schematic diagram of a PPA including pulse power battery trays.

FIGS. 10-12 shown plots of an example PPA operating sequence.

### DETAILED DESCRIPTION

Embodiments of PPAs that include the high power and low voltage cell characteristics of nickel/zinc battery cells to mitigate load pulses (e.g., GPU load pulses) at a DC bus voltage level are described (e.g., 1.1 VDC for a GPU). The described PPAs may compensate the pulse power issues at an electric load (e.g., a GPU) source so that there may be no reason for increases in utility power and electric load infrastructure power to compensate for pulse power issues. Nickel/zinc battery power density, response times, energy density, discharge voltage characteristics, and lower cost per watt hour of storage that make the PPA systems described herein a compelling pulse power solution alternative to capacitors. This is especially true in technology environments where the power, duration, and frequency of GPU pulse load durations are subject to changes according to GPU model and AI processing applications. While the methods and system described herein includes nickel/zinc battery cells it may be appreciated that the methods and circuitry described herein may be applied to systems that apply other types of battery cells.

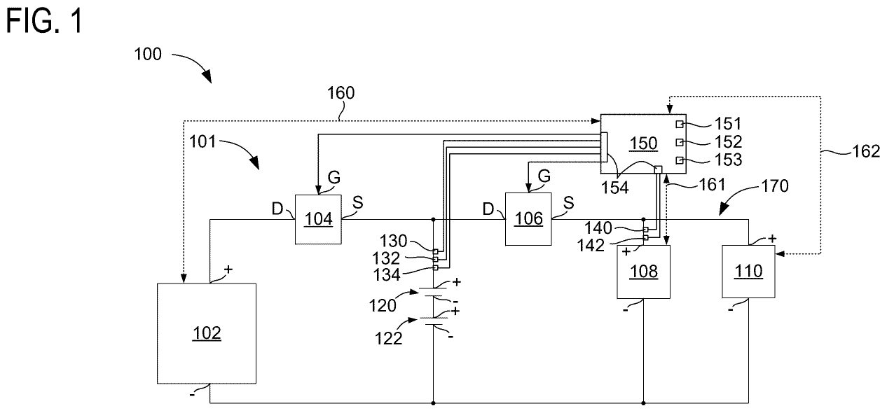

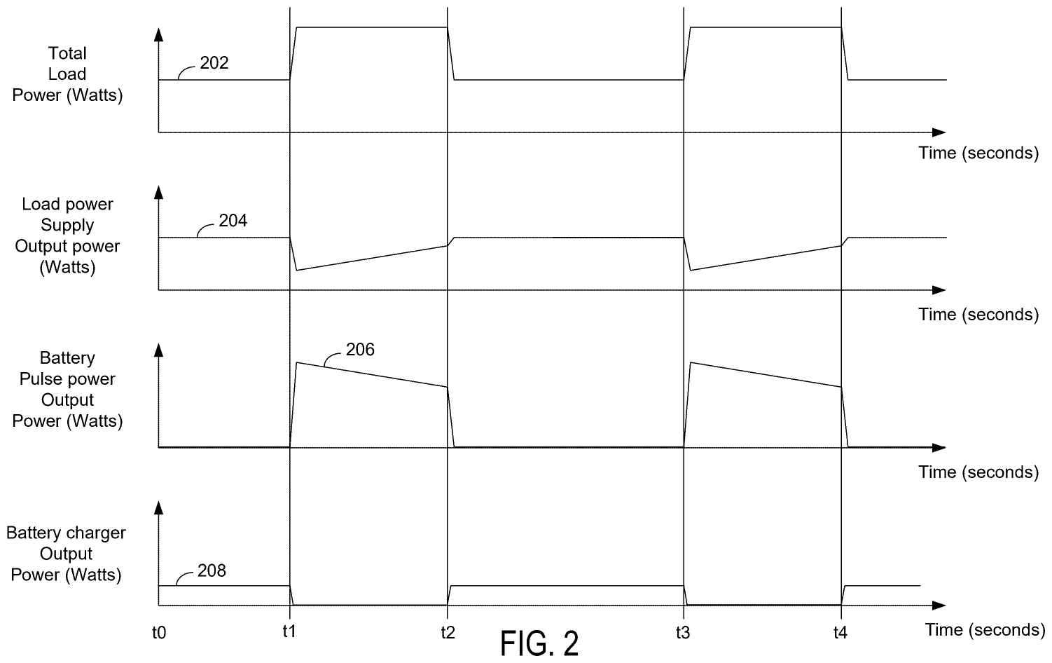

FIG. 1 shows a first example embodiment of a PPA. The PPA may operate as shown in the operating sequence of FIG. 2. Applying the concepts and methods that are described herein, a PPA may be constructed to provide a determined voltage at a determined amount of power from battery cells. The PPA may apply nickel/zinc battery cells, or alternative battery chemistries, to provide the determined voltage and power levels. FIG. 1 shows two nickel/zinc battery cells that are arranged in series to deliver electric power to an electric load, but it may be appreciated that the arrangement shown in FIG. 1 is not to be considered as constraining the extents of the present description.

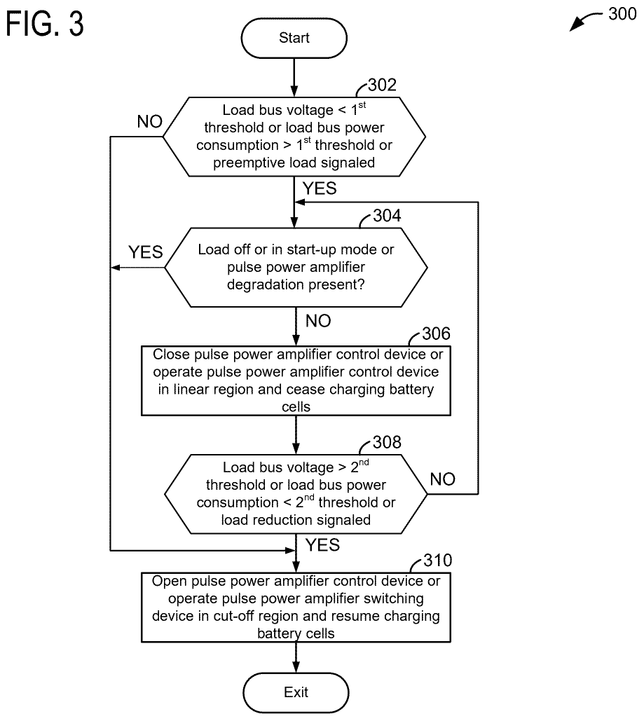

The voltage output waveform from the nickel/zinc cell's pulse power is especially easy for traditional GPU PSU units to regulate to a determined voltage (e.g., 1.1 V as specified by the GPU). The PPA low power charge circuit included in the PPA enables the nickel/zinc battery to recover the charge that is lost in a prior pulse load compensating discharge. Unlike capacitors with constrained energy storage, the PPA may provide hundreds of pulse-load compensating discharges before receiving a full regenerative charge. In one example, a PPA may apply a low cost MOSFET switch with desired value of RDSon enabled PPA output power that is in a range that is easily regulated to a determined voltage (e.g., 1.1 V by the GPU PSU). The financial expense of simplified switched recharge power in a discharge power out solution may be 1/10 the expense of more complicated DC/DC converters and their capacitors. A method for operating the PPA is shown in the flowchart of FIG. 3.

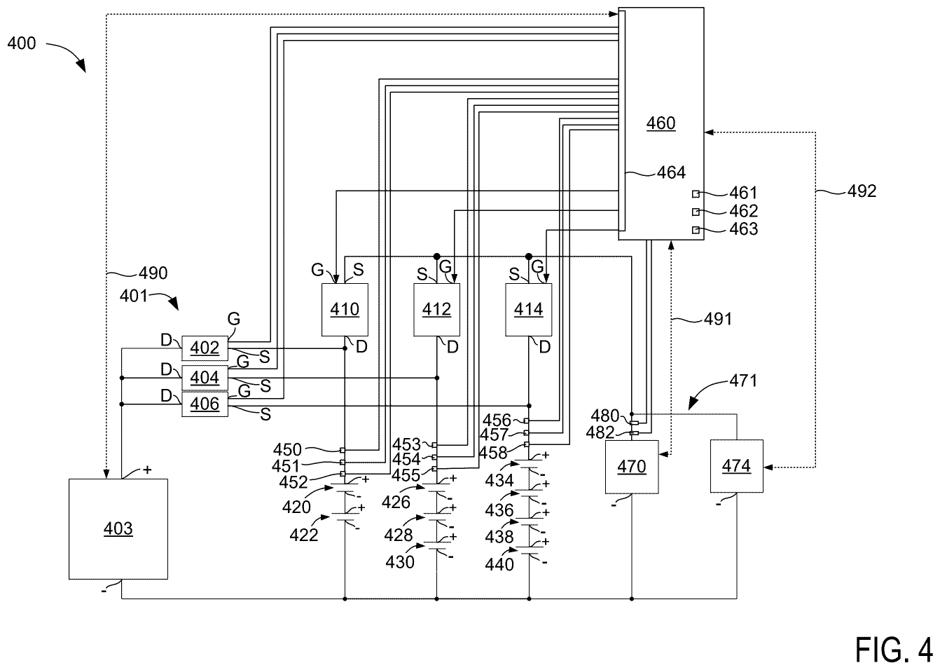

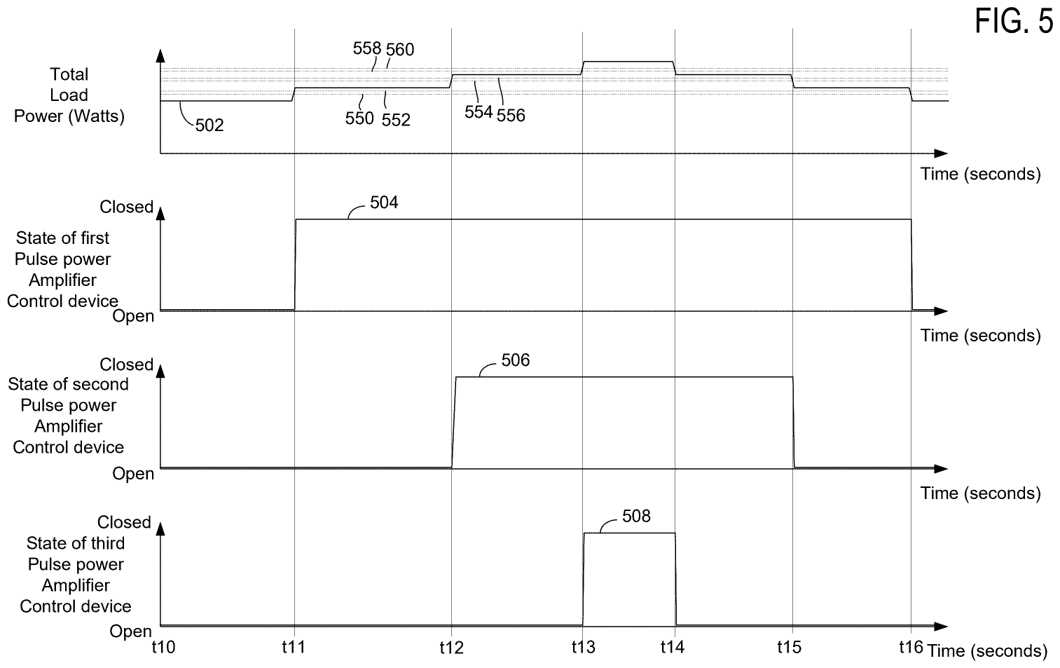

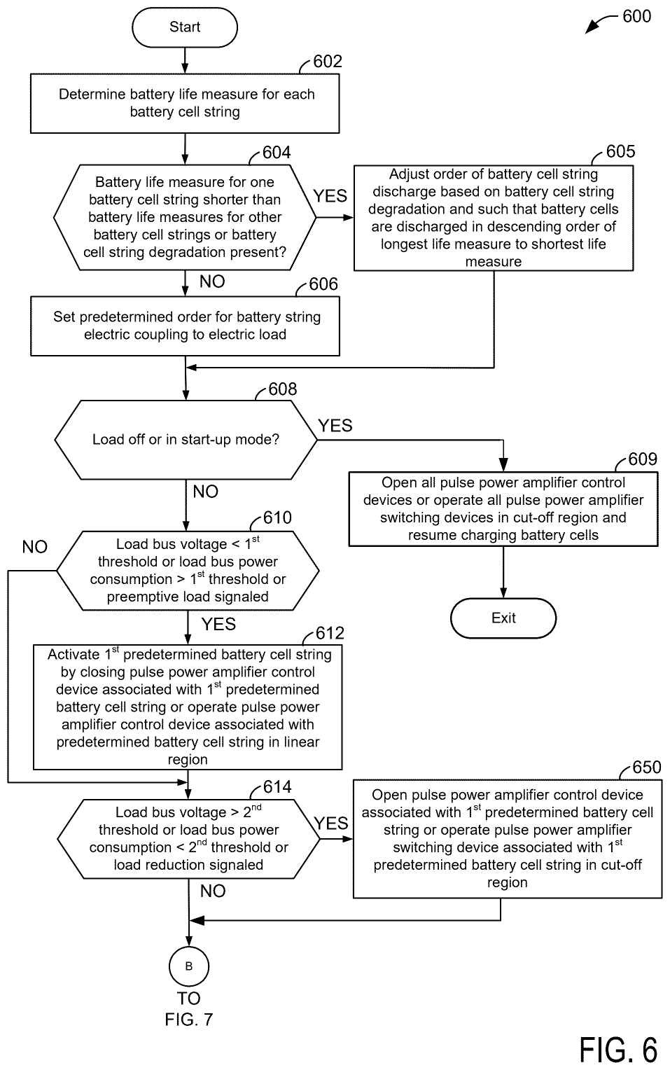

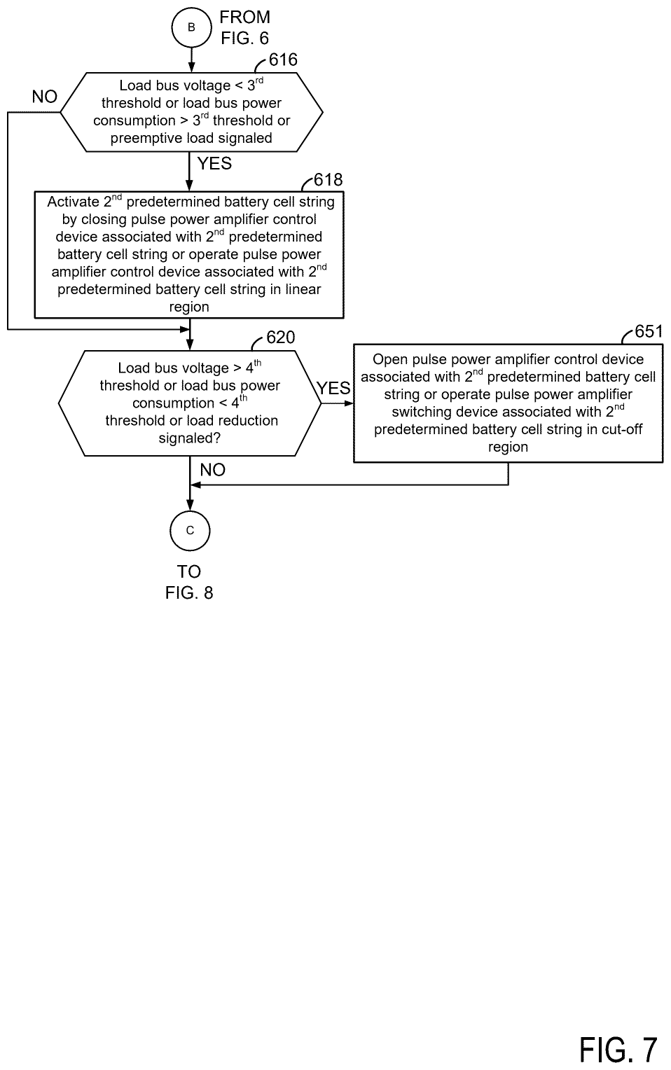

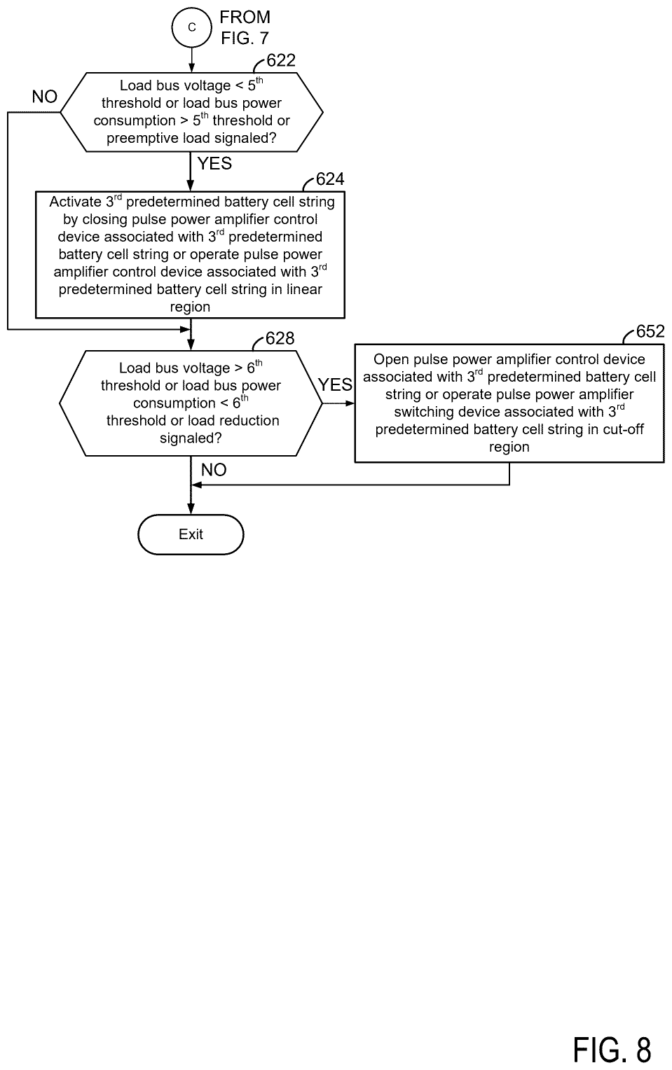

A second embodiment is shown in FIG. 4. The first embodiment may be at least partially incorporated into the second embodiment. In this example, the actual total number of battery cells in each parallel string selected is a run time variable enabled by connection and disconnection control signals. Nickel/zinc battery chemistry is particularly suited to this type of unbalanced cell count string discharge control method because nickel/zinc is a rather benign chemistry. Further, nickel/zinc chemistry has a broad range of discharge power potential. The approach included herein supports a new and novel battery voltage control that may lower the variability of battery discharge voltages from a maximum of 40% to a few percent that results from being able to apply float charging instead of full voltage charging to discharged battery cells and immediate float charging after battery cells are discharged so that higher states of charge may be maintained in the battery cells. In some examples, voltage sensing of the electric load supports control methods by informing the controller of the current voltage and direction of change in voltage. The parallel strings may be selectively electrically coupled to the electric load as shown in the sequence of FIG. 5. A control method that connects strings with progressively more battery cells to the electric load when a voltage of the electric load is low is shown in FIGS. 6-8.

As an alternative, or additionally, the PPA control method may apply load power information transmission to the switch between activated battery cell strings. The load power information enables the connection and disconnection of battery strings as desired to exactly offset changes in load power. In this way, the battery system may support variable load conditions without significant changes in load voltage.

FIG. 1 illustrates a schematic block diagram of a first example PPA. Solid lines that are shown between the various components and blocks represent conductors. Dashed lines may or may not be conductors, but these dashed lines represent communication links that may be wired, fiber optic, or wireless. Herein, “directly electrically coupled” is defined as there are no intervening electric power sources, electric power consumers, or electrically activated devices that electric power flows through between the two directly electrically coupled devices. The two electrically coupled devices may have conductors and wiring blocks between them and still remain within the definition of directly electrically coupled. It is appreciated that sensors described herein (e.g., voltage, temperature, and current) are to be understood as not affecting whether or not two components are to be understood to be directly electrically coupled together even though there may be a sensor along a conductor that electrically couples the two devices that are directly electrically coupled. While the schematic block diagram of FIG. 1 illustrates two battery cells arranged in series, it may be appreciated that the approach shown in FIG. 1 may be extended to N (e.g., where N in an integer variable) battery cells arranged in series. Further, the approach of FIG. 1 may be extended to N strings of battery cells arranged in parallel as shown in FIG. 4. The battery cells shown in FIG. 1 may be nickel/zinc battery cells.

PPA 100 includes a charging circuit 101 that comprises charger 102 and charger control device 104. Charger control device 104 may be a low power transistor (e.g., metal oxide semi-conductor field effect transistor (MOSFET), bi-polar junction transistor BJT, or other known transistor or silicon controlled rectifier that may operate as a switch), mechanical relay, or solid state relay. However, for illustration purposes in this example, charger control device 104 is shown as a MOSFET with a drain terminal (D), a gate terminal (G) (indicated by G), a source terminal (S). In some examples, controller 150 may also be included in the charging circuit 101. The positive terminal + of charger 102 is shown directly electrically coupled to the drain terminal D (e.g., a first load terminal of the device) of charger control device 104. The source terminal S of charger control device 104 (e.g., a second load terminal of the device) is directly electrically coupled to the positive terminal + of first battery cell 120. The gate terminal G of charger control device 104 is directly electrically coupled to controller 150. Charger 102 may supply a predetermined voltage (e.g., 2.2 VDC) to charger control device 104. Controller 150 is directly electrically coupled to gate terminal G of charger control device 104 (e.g., a control terminal of the device) and controller 150 may apply a voltage to gate terminal G of charger control device 104 to close the charger control device 104 (e.g., operating in a saturation region) so that electric current may flow from the charger to first battery cell 120 and second battery cell 122 so that they may be recharged. Thus, closing the charger control device charges each battery cell in a battery cell string that is associated with the charger control device. Controller 150 may adjust a voltage supplied to gate terminal G of charger control device 104 to a voltage that causes the charger control device 104 (e.g., operating in the cut-off region) to open so that electric current may not flow from the charger 102 to first battery cell 120 and second battery cell 122. Optionally, a communications link 160 may be provided between controller 150 and charger 102. The charger 102 may communicate its status, charging/not charging, etc. and receive instructions from controller 150 (e.g., enable, disable, etc.).

In this example, PPA 100 includes a first battery cell 120 that includes a positive terminal+ and a negative terminal − as indicated. PPA 100 also includes a second battery cell 122 that includes a positive terminal+ and a negative terminal − as indicated. The negative terminal of the first battery cell 120 is directly electrically coupled to the positive terminal of the second battery cell 122 such that first battery cell 120 is arranged in series with second battery cell 122. The negative terminal of second battery cell 122 is directly electrically coupled to the negative terminals of charger 102, electric load 108, and PSU 110. First battery cell 120 and second battery cell 122 may be referred to as a string of battery cells or a battery cell string since they are electrically coupled in series. Herein, a battery cell string may comprise a sole battery cell, or alternatively, two or more battery cells arranged in series.

PPA 100 also includes a pulse power amplifier control device 106. In some examples, pulse power amplifier control device 106 may operate as a high power switch. In other examples, pulse power amplifier control device 106 may operate as variable resistor while operating a linear operating mode of the device. This allows the pulse power amplifier control device to operate as a power control device and voltage regulation device instead of having to have a power supply to provide regulation.

Pulse power amplifier control device 106 is a high power device that is configured to control flow of electric current between battery cells and electric load 108 (e.g., a GPU, combined GPU/CPU, etc.). Pulse power amplifier control device 106 may be a high power transistor (e.g., metal oxide semi-conductor field effect transistor (MOSFET), bi-polar junction transistor BJT, or other known transistor or silicon controlled rectifier that may operate as a switch), mechanical relay, or solid state relay. In other examples, pulse power amplifier control device 106 may be a high power diode where an anode of the high power diode is directly electrically coupled to the positive terminal of first battery cell 120 and a cathode of the high power diode is directly electrically coupled to the positive terminal of the electric load. However, for illustration purposes in this example, pulse power amplifier control device 106 is shown as a MOSFET with a drain terminal (D), a gate terminal (G) (indicated by G), a source terminal (S). The positive terminal+first battery cell 120 is shown directly electrically coupled to the drain terminal D of pulse power amplifier control device 106. The source terminal S of pulse power amplifier control device 106 is directly electrically coupled to the positive terminal + of electric load 108. The gate terminal G of pulse power amplifier control device 106 is directly electrically coupled to controller 150. Controller 150 is directly electrically coupled to gate terminal G of pulse power amplifier control device 106 and controller 150 may apply a voltage to gate terminal G of pulse power amplifier control device 106 to close the pulse power amplifier control device 106 (e.g., operating in a saturation region) so that electric current may flow from the first battery cell 120 to positive terminal of the electric load 108 during conditions when electric load 108 is pulsed to increase electric power consumption of electric load 108. Controller 150 may adjust a voltage supplied to gate terminal G of pulse power amplifier control device 106 to a voltage that causes the pulse power amplifier control device 106 (e.g., operating in the cut-off region) to open so that electric current may not flow from the first battery cell 120 to the electric load 108.

The PPA 100 may provide pulsed electric power to electric load 108 in response to voltage of a DC bus 170 (e.g., an electric conductor) supplying DC power to positive terminal (indicated by +) or electric load 108. A PSU 110 is arranged in parallel with electric load 108 such that a positive terminal (indicated by +) is electrically coupled to the positive terminal of the electric load 108. As previously mentioned, electric load 108 may be a GPU, combined GPU/CPU, or other pulsed electric load.

PPA 100 also includes a controller 150. In some examples, controller 150 may be comprised of analog circuitry (e.g., operational amplifiers, comparators, ect.), digital circuitry (e.g., AND gates, OR gates, NAND gates, etc.), a combination of analog and digital circuitry, or a microcontroller. For example, in a simple embodiment, controller 150 may apply analog circuitry to command charger control device 104 closed when the analog circuitry determines that a voltage at the positive terminal of electric load 108 is less than the first predetermined voltage. Further, controller 150 may apply the analog circuitry to command the charger control device 104 open when the analog circuitry determines that the voltage at the positive terminal of electric load 108 is greater than a second predetermined voltage. Thus, the analog circuitry may perform the method of FIG. 3. In other examples, where controller 150 is more sophisticated, controller 150 may execute the method of FIG. 3 via a microcontroller.

In this example, controller 150 includes a microcontroller 151, read exclusive memory (e.g., non-transitory memory) 152, random-access memory 153, and inputs and outputs 154 (e.g., digital inputs/outputs and analog inputs). Controller 150 may communicate with charger 102 via communications link 160. Similarly, controller 150 may communicate with electric load 108 via communications link 161. Controller 150 may determine battery current flow from current flow sensor 130, battery voltage from voltage sensor 132, and battery temperature from temperature sensor 134. Similarly, controller 150 may determine a voltage at electric load 108 or DC bus 170 that supplies DC power to electric load 108 via voltage sensor 140. Controller 150 may also determine an amount of electric current flowing into electric load 108 via current sensor 142. Further, in some examples, controller 150 may send and receive control information and data from PSU 110 via communications link 162. For example, PSU 110 may communicate to controller 150 that it is unable to regulate voltage of the DC bus within a predetermined voltage range.

In this way, PPA 100 may transfer electric power from nickel/zinc battery cells to an electric load via simply closing a high power switching device. PSU 110 may supply electric power to electric load 108 during nominal operating conditions, but when electric load 108 increases electric power consumption to increase computations, the nickel/zinc batteries may be electrically coupled to the electrical load such that just a small voltage drop occurs across the pulse power amplifier control device 106. The first battery cell 120 in series with the second battery cell 122 may output a determined voltage (e.g., between 1.3 volts and 3.9 volts) so that a determined voltage (e.g., 1.1 volts) may be supplied to the electric load following a voltage drop (e.g., a one volt drop) across the pulse power amplifier control device 106.

Referring now to FIG. 2, an example operating sequence for the system of FIG. 1 according to the method of FIG. 3 is shown. The sequence of FIG. 3 may be provided via the system of FIG. 1 in cooperation with the method of FIG. 3. The plots of FIG. 2 are time aligned. The vertical lines represent times if interest during the sequence.

The first plot from the top of FIG. 2 is a plot of a total load power that is consumed by the electric load (e.g., 108 of FIG. 1) versus time. The vertical axis represents power consumed in units of watts and the amount of power consumed increases in the direction of the vertical axis arrow. The horizontal axis represents time and time increases from the left side of the plot to the right side of the plot.

The second plot from the top of FIG. 2 is a plot of a total power supply output power from the PSU (e.g., 110 of FIG. 1) versus time. The vertical axis represents power output by the PSU in units of watts and the amount of power output increases in the direction of the vertical axis arrow. The horizontal axis represents time and time increases from the left side of the plot to the right side of the plot.

The third plot from the top of FIG. 2 is a plot of a total power supply output power from the nickel/zinc battery cells (e.g., 120 and 122 of FIG. 1) versus time. The vertical axis represents power output by the battery cells in units of watts and the amount of power output increases in the direction of the vertical axis arrow. The horizontal axis represents time and time increases from the left side of the plot to the right side of the plot.

The fourth plot from the top of FIG. 2 is a plot of a total battery charger output power that is supplied by the charger (e.g., 102 of FIG. 1) to the battery cells (e.g., 120 and 122 of FIG. 1) versus time. The vertical axis represents power output in units of watts and the amount of power output increases in the direction of the vertical axis arrow. The horizontal axis represents time and time increases from the left side of the plot to the right side of the plot.

At time t0, the total amount of electric power that is consumed by the electric load is a middle level and the power supply provides off of this power to the electric load. The battery pulse power output is zero and the battery charger is supplying charge to the battery cells.

At time t1, the electric load increases causing a voltage at the DC bus and positive terminal of the electric load to roll off and decline (not shown). In response to the lower voltage at the DC bus and at the positive terminal of the electric load, power is delivered from the battery cells to the electric load. The increased power flow to the DC bus from the battery cells allows the PSU output power to decline since the PSU is controlling to a target voltage (e.g., 1.1 volts). The battery pulse power increases and charging of the battery cells is suspended causing the charger output power to fall to zero. The battery pulse power output gradually decays between time t1 and time t2. The PSU power output gradually increases as the battery pulse power gradually declines. The combination of the PSU output power and the battery power output is a constant amount of power.

At time t2, the electric load decreases causing an increasing voltage at the DC bus and positive terminal of the electric load (not shown). In response to the higher voltage at the DC bus and at the positive terminal of the electric load, power delivery from the battery cells to the electric load is suspended or ceased. The decreased power flow to the DC bus allows the PSU output power to increase since the PSU is controlling to a target voltage (e.g., 1.1 volts). The battery pulse power decreases and charging of the battery cells commences shortly after time t2. The battery pulse power output returns to zero shortly after time t2. The PSU power output gradually increases after time t2 as the electric load power consumption declines.

At time t3, the electric load increases for a second time causing a voltage at the DC bus and positive terminal of the electric load to roll off and decline (not shown). In response to the lower voltage at the DC bus and at the positive terminal of the electric load, power is delivered from the battery cells to the electric load. The increased power flow to the DC bus from the battery cells allows the PSU output power to decline since the PSU is controlling to a target voltage. The battery pulse power increases and charging of the battery cells is suspended causing the charger output power to fall to zero. The battery pulse power output gradually decays between time t3 and time t4. The PSU power output gradually increases as the battery pulse power gradually declines. The combination of the PSU output power and the battery power output is a constant amount of power.

At time t4, the electric load decreases for a second time causing an increasing voltage at the DC bus and positive terminal of the electric load (not shown). In response to the higher voltage at the DC bus and at the positive terminal of the electric load, power delivery from the battery cells to the electric load is suspended or ceased. The decreased power flow to the DC bus allows the PSU output power to increase since the PSU is controlling to a target voltage. The battery pulse power decreases and charging of the battery cells commences shortly after time t4. The battery pulse power output returns to zero shortly after time t4. The PSU power output gradually increases after time t4 as the electric load power consumption declines.

In this way, pulses of DC power may be supplied to an electric load to compensate for power increases that may be large, but relatively short in duration. During periods when voltage and power boosting is not activated, a charger may at least partially recharge partially discharged battery cells. Since output voltage of the batteries is close to a voltage specified by the electric load, complex buck or boost power supply circuitry may be avoided.

Referring now to FIG. 3, a method for operating a PPA system is shown. The method of FIG. 3 may be performed by a controller that is comprised of analog circuitry, digital circuitry, a combination of analog and digital circuitry, or a microcontroller. In cases where the method of FIG. 3 is performed via a controller, the method of FIG. 3 may be stored as executable instructions stored in non-transitory memory of the controller. The method of FIG. 3 may operate in cooperation with the system of FIG. 1. In addition, the method of FIG. 3 may generate the operating sequence of FIG. 2.

At 302, method 300 judges whether or not a load bus voltage (e.g., a voltage at a positive power terminal of an electric load or a voltage of a bus that supplies electric power to an electric load) is less than a first threshold voltage, or alternatively, if load bus electric power consumption (e.g., a rate of electric power consumption by an electric load that is fed power via a bus) is greater than a first threshold power consumption rate. If so, the answer is yes and method 300 proceeds to 304. If not, the answer is no and method 300 proceeds to 310. If method 300 determines that one or more battery cells are degraded, method 300 may communicate an inability to boost the voltage at the electric load to the electric load.

Some electric loads (e.g., GPUs, combinations of GPUs and CPUs, etc.) may have a capacity to indicate that a computational load (e.g., rate of GPU instructions performed) is expected to increase before the computational load actual increases, and along with it, a corresponding power consumption increase from the electric load. If an electric load with such capacity is present, method 300 may receive the preemptive power consumption information before the load bus voltage drops or the load bus power consumption rate increases. This allows the controller (e.g., 150 of FIG. 1) to electrically couple the battery cell string (e.g., comprising nickel/zinc battery cells) to the electric loads before, or simultaneously with, the time that the electrical load is expected to increase. Therefore, if method 300 receives such information at 302 before a voltage drop or power consumption increase, method 300 may proceed to 304.

At 304, method 300 judges whether or not the electrical load has been commanded off, if the electric load is in a power-up mode, and/or if degradation of the battery cells is present. Method 300 may receive this information from the electric load via communication link and via the controller itself performing diagnostics on the battery cell strings. If method 300 judges that electrical load has been commanded off, if the electric load is in a power-up mode, and/or if degradation of the battery cell strings is present, the answer is yes and method 300 proceeds to 310. Otherwise, the answer is no and method 300 proceeds to 306. Thus, during these conditions, the PPA may not electrically couple the battery cells to the electrical load to inhibit undesirable switching.

At 306, method 300 closes the pulse power amplifier control device (e.g., 106 of FIG. 1), or alternatively, operates the pulse power amplifier control device in a linear mode such that the pulse power amplifier operates as a voltage controlled variable resistor. Closing the pulse power amplifier control device electrically couples the battery cells (e.g., nickel/zinc) to the electric load so that the battery cells may boost electric power that is supplied to the electric load (e.g., 108 of FIG. 1) and mitigate a possibility of further DC bus voltage reduction. As such, the electric load may be supplied with a voltage that is within its specifications. Additionally, method 300 opens the charger control device (e.g., 104 of FIG. 1) so that charging of the battery cells ceases while the battery cells are supplying power to the electric load. This action helps to ensure that the charger is not exposed to larger loadings. The battery charger may remain activated. Method 300 proceeds to 308.

At 308, method 300 judges whether or not a load bus voltage (e.g., a voltage at a positive power terminal of an electric load or a voltage of a bus that supplies electric power to an electric load) is greater than a second threshold voltage, or alternatively, if load bus electric power consumption (e.g., a rate of electric power consumption by an electric load that is fed power via a bus) is less than a second threshold power consumption rate. The second threshold voltage is greater than the first threshold voltage and the second threshold power consumption rate is less than the first threshold power consumption rate. If method 300 judges that the load bus voltage is greater than a second threshold voltage or that the load bus electric power consumption is less than a second threshold power consumption rate, the answer is yes and method 300 proceeds to 310. If not, the answer is no and method 300 returns to 304.

At 310, method 300 opens the pulse power amplifier control device. Opening the pulse power amplifier control device electrically decouples the battery cells from the electric load so that the power flow from the battery cells ceases. Additionally, method 300 closes the charger control device so that charging of the battery cells resumes while the battery cells are not supplying power to the electric load. This action helps to ensure that the battery cells are recharged for subsequent loading. Method 300 proceeds to exit.

Thus, the method of FIG. 3 may selectively electrically couple battery cells (e.g., nickel/zinc battery cells in a battery cell string) to an electric load that exhibits pulse power consumption. The approach may reduce a possibility of a DC bus voltage falling below levels specified for a particular electric load, such as a GPU. Additionally, the approach controls charging of the battery cells such that charging of the battery cells does not conflict with discharging of the battery cells.

Turning now to FIG. 4, a schematic block diagram of a second PPA 400 is shown. The second PPA includes circuitry that is similar to the PPA of FIG. 1, but in this example, strings of battery cells are arranged in parallel. The second PPA 400 may be useful to extend battery cell life cycle, supply greater amounts of electric power, and offer options if particular battery cells experience degradation.

In FIG. 4, solid lines that are shown between the various components and blocks represent conductors. Dashed lines may or may not be conductors, but these dashed lines represent communication links that may be wired, fiber optic, or wireless. It is appreciated that sensors described herein (e.g., voltage, temperature, and current) are to be understood as not affecting whether or not two components are to be understood to be directly electrically coupled together even though there may be a sensor along a conductor that electrically couples the two devices. While the schematic block diagram of FIG. 3 illustrates two, three, and four battery cells arranged in series, it may be appreciated that the approach shown in FIG. 3 may be extended to N (e.g., where N in an integer variable) battery cells arranged in series. Further, FIG. 3 shows three battery strings arranged in parallel, but the approach may be extended to X (e.g., where X in an integer variable) strings of battery cells arranged in parallel. The battery cells shown in FIG. 4 may be nickel/zinc battery cells.

PPA 400 includes a charging circuit 401 that comprises charger 403 and charger control devices 402, 404, and 406, which are arranged in parallel. Controller 460 may also be included in the charging circuit 401. The charger control devices 402, 404, and 406 may be the same as charger control device 104 shown in FIG. 1. However, in this example, charger control devices 402, 404, and 406 are shown as low power MOSFETs with a drain terminal (D), a gate terminal (G) (indicated by G), a source terminal (S). The positive terminal + of charger 403 is shown directly electrically coupled to the drain terminals D of charger control devices 402, 404, and 406. The source terminal S of first charger control device 402 is directly electrically coupled to the positive terminal + of first battery cell 420 (e.g., a first battery cell in FIG. 4 and a first battery cell in a first battery cell string). The gate terminal G of charger control device 402 is directly electrically coupled to controller 460. The source terminal S of second charger control device 404 is directly electrically coupled to the positive terminal + of third battery cell 426 (e.g., a third battery cell in FIG. 4 and a first battery cell in a second battery cell string). The gate terminal G of second charger control device 404 is directly electrically coupled to controller 460. The source terminal S of third charger control device 406 is directly electrically coupled to the positive terminal + of sixth battery cell 434 (e.g., a sixth battery cell in FIG. 4 and a first battery cell in a third battery cell string). The gate terminal G of third charger control device 406 is directly electrically coupled to controller 460.

Charger 403 may supply a predetermined voltage (e.g., 2.2 VDC) to charger control devices 402, 404, and 406. Controller 460 is directly electrically coupled to gate terminals G of charger control devices 402, 404, and 406. Controller 460 may independently apply voltages to gate terminals G of charger control devices 402, 404, and 406 to independently close the charger control devices 402, 404, 406 so that electric current may flow from the charger independently to first battery cell 420, third battery cell 426, and sixth battery cell 434 so that they may be recharged. Controller 460 may independently adjust voltages of gate terminals G of charger control devices 402, 404, and 406 104 to independently open the charger control devices 402, 404, and 406 so that electric current may not flow from the charger to first battery cell 420, third battery cell 426, and sixth battery cell 434. Optionally, a communications link 490 may be provided between controller 460 and charger 403. The charger 403 may communicate its status, charging/not charging, etc. and receive instructions from controller 460 (e.g., enable, disable, etc.).

In this example, PPA 400 includes first string of battery cells including a first battery cell 420 that includes a positive terminal+ and a negative terminal − as indicated. A second battery cell 422 is also included in the first string of battery cells that includes a positive terminal+ and a negative terminal − as indicated. The positive terminal of the second battery cell 422 is directly electrically coupled to the negative terminal of the first battery cell 420 such that first battery cell 420 is arranged in series with second battery cell 422. The negative terminal of second battery cell 422 is directly electrically coupled to the negative terminals of charger 403, electric load 470, and PSU 474.

PPA 400 also includes second string of battery cells including a third battery cell 426, a fourth battery cell 428, and a fifth battery cell 430. The terminals of the third, fourth, and fifth battery cells are indicated similarly to the first and second battery cells. The third, fourth, and fifth battery cells are also arranged in series. The negative terminal of fifth battery cell 430 is directly electrically coupled to the negative terminals of charger 403, electric load 470, and PSU 474.

PPA 400 also includes third string of battery cells including a sixth battery cell 434, a seventh battery cell 436, an eighth battery cell 438, and a ninth battery cell 440. The terminals of the sixth, seventh, eighth, and ninth battery cells are indicated similarly to the first and second battery cells. The sixth, seventh, eighth, and ninth battery are also arranged in series. The negative terminal of ninth battery cell 440 is directly electrically coupled to the negative terminals of charger 403, electric load 470, and PSU 474.

PPA 400 also includes a first pulse power amplifier control device 410, a second pulse power amplifier control device 412, and a third pulse power amplifier control device 414 that may independently selectively control power flow from the first string of battery cells, the second string of battery cells, and the third string of battery cells to electric load 470. In some examples, pulse power amplifier control devices may operate as high power switches. In other examples, pulse power amplifier control devices may operate as variable resistors while operating a linear operating mode of the devices. Pulse power amplifier control devices 410, 412, 414 may be the same device as pulse power amplifier control device 106 shown in FIG. 1.

Pulse power amplifier control devices 410, 412, and 414 are high power devices that are configured to control flow of electric current between battery cells and electric load 470 (e.g., a GPU, combined GPU/CPU, etc.). Pulse power amplifier control devices 410, 412, and 414 may be a high power transistor (e.g., metal oxide semi-conductor field effect transistor (MOSFET), bi-polar junction transistor BJT, or other known transistor or silicon controlled rectifier that may operate as a switch), mechanical relay, or solid state relay. However, for illustration purposes in this example, pulse power amplifier control devices 410, 412, and 414 are shown as MOSFETs with a drain terminal (D), a gate terminal (G) (indicated by G), a source terminal (S).

The positive terminal + of first battery cell 420 is shown directly electrically coupled to the drain terminal D of first pulse power amplifier control device 410. The source terminal S of first pulse power amplifier control device 410 is directly electrically coupled to the positive terminal + of electric load 470. The gate terminal G of first pulse power amplifier control device 410 is directly electrically coupled to controller 460. Similarly, the positive terminal + of third battery cell 426 is shown directly electrically coupled to the drain terminal D of second pulse power amplifier control device 412. The source terminal S of second pulse power amplifier control device 412 is directly electrically coupled to the positive terminal + of electric load 470. The gate terminal G of second pulse power amplifier control device 412 is directly electrically coupled to controller 460. Likewise, the positive terminal + of sixth battery cell 434 is shown directly electrically coupled to the drain terminal D of third pulse power amplifier control device 414. The source terminal S of third pulse power amplifier control device 414 is directly electrically coupled to the positive terminal + of electric load 470. The gate terminal G of third pulse power amplifier control device 414 is directly electrically coupled to controller 460.

Controller 460 may independently apply voltages to gate terminals G of pulse power amplifier control devices 410, 412, and 414 to close the pulse power amplifier control devices so that electric current may flow from the battery cells to the positive terminal of the electric load 470 during conditions when electric load 470 is pulsed and electric power consumption of electric load 470 is increased. Controller 460 may independently adjust voltages from gate terminals G of pulse power amplifier control devices 410, 412, and 414 such that the gates are at a voltage that causes the pulse power amplifier control devices to open so that electric current may not flow from the battery cells to the electric load 470.

The PPA 400 may provide pulsed electric power to electric load 470 in response to voltage of a DC bus 471 (e.g., an electric conductor) supplying DC power to positive terminal (indicated by +) or electric load 470. A PSU 474 is arranged in parallel with electric load 470 such that its positive terminal (indicated by +) is electrically coupled to the positive terminal of the electric load 470.

PPA 400 also includes a controller. In some examples, controller 460 may be comprised of analog circuitry (e.g., operational amplifiers, comparators, etc.), digital circuitry (e.g., AND gates, OR gates, NAND gates, etc.), a combination of analog and digital circuitry, or a microcontroller. Thus, the analog and/or digital circuitry may perform the method of FIGS. 6-8. In other examples, where controller 460 is more sophisticated, controller 460 may execute the method of FIGS. 6-8 via a microcontroller.

In this example, controller 460 includes a microcontroller 461, read exclusive memory (e.g., non-transitory memory) 462, random-access memory 463, and inputs and outputs 464 (e.g., digital inputs/outputs and analog inputs). Controller 460 may communicate with charger 403 via communications link 490. Similarly, controller 460 may communicate with electric load 470 via communications link 491. Controller 460 may determine battery current flow for each of the individual battery strings from current flow sensors 450, 453, and 456. Controller 460 may determine battery voltage for each of the individual battery strings from voltage sensors 451, 454, and 457. Controller 460 may determine battery temperatures for each of the individual battery strings from temperature sensor 452, 455, and 458. Similarly, controller 460 may determine a voltage at electric load 470 or DC bus 471 that supplies DC power to electric load 470 via voltage sensor 480. Controller 460 may also determine an amount of electric current flowing into electric load 470 via current sensor 482. Further, in some examples, controller 460 may send and receive control information and data from PSU 474 via communications link 492. For example, PSU 474 may communicate to controller 460 that it is unable to regulate voltage of the DC bus within a predetermined voltage range.

In this way, PPA 400 may selectively and independently transfer electric power from each battery string to an electric load via simply closing one or more high power switching devices. PSU 474 may supply electric power to electric load 470 during nominal operating conditions, but when electric load 470 increases electric power consumption to increase computations, one or more battery strings may be electrically coupled to the electrical load such that just a small voltage drop occurs across each pulse power amplifier control device.

In this example, the first string of battery cells includes two battery cells whereas the second and third battery cell strings include three and four battery cells respectively. Nickel/zinc battery cell characteristics allow battery cell strings with different actual total numbers of battery cells to be arranged in parallel without resulting in significant charge redistribution between the battery cells. While in this example, battery cell strings of two, three, and four battery cells may be included in PPA 400, it may be appreciated that the battery strings may comprise different numbers of battery cells that are arranged in series (e.g., 20, 22, and 24 cells in three different battery strings). Further, it may be appreciated that the PPA shown in FIG. 4 may be extended to arrangements with two or more battery cell strings arranged in parallel.

The systems of FIGS. 1 and 4 provide for a pulse power amplifier, comprising: a battery cell string; a pulse power amplifier control device electrically coupled to the battery cell string; and a controller configured to control electric power flow through the pulse power amplifier control device in response to a voltage of an electric load or an amount of electric power consumed by the electric load, where the amount of electric power consumed by the electric load may be indicated via a signal (e.g., a current output signal, a voltage output signal, or a data value output signal). In a first example, the pulse power amplifier includes where pulse power amplifier control device is a transistor, diode, and/or other solid state switching device. In a second example that may include the first example, the pulse power amplifier includes where the battery cell string includes a first battery cell and a second battery cell that are nickel/zinc battery cells and that include a negative zinc electrode and a positive nickel electrode. In a third example that may include one or both of the first and second examples, the pulse power amplifier includes where the controller is configured to close the pulse power amplifier control device in response to the voltage being less than a threshold voltage and/or the amount of electric power consumed by the electric load exceeding a threshold amount of power. In a fourth example that may include one or more of the first through third examples, the pulse power amplifier further comprises a charger and a charger control device, where the charger is directly electrically coupled to the charger control device, and where the charger control device is directly electrically coupled to the battery cell string. In a fifth example that may include one or more of the first through fourth examples, the pulse power amplifier further comprises a power supply arranged in parallel with the electric load. In a sixth example that may include one or more of the first through fifth examples, the pulse power amplifier further comprises a second battery cell string and a second pulse power amplifier control device arranged in parallel with the battery cell string and the pulse power amplifier control device. In a seventh example that may include one or more of the first through sixth examples, the pulse power amplifier includes where the battery cell string includes a first actual total number of battery cells arranged in series, where the second battery cell string includes a second actual total number of battery cells arranged in series, and where the second actual total number of battery cells is different than the first actual total number of battery cells. In an eighth example that may include one or more of the first through seventh examples, the pulse power amplifier further comprises a charger and a first charger control device and a second charger control device, where the first charger control device is directly electrically coupled to the battery cell string, and where the second charger control device is directly electrically coupled to the second battery cell string.

The systems of FIGS. 1 and 4 also provide for a pulse power amplifier, comprising: a battery cell string; a pulse power amplifier control device electrically coupled to the battery cell string; and a controller configured to control electric power flow through the pulse power amplifier control device and control electric power flow through a charger control device in response to a voltage of an electric load and/or an amount of electric power consumed by the electric load. In a first example, the pulse power amplifier further comprises a communications link between a charger and the controller. In a second example that may include the first example, the pulse power amplifier further comprises a communications link between the controller and the electric load. In a third example that may include one or both of the first and second examples, the pulse power amplifier includes where the electric load is a graphics processing unit, where the battery cell string includes a first battery cell and a second battery cell, where the battery cell string is included in a plurality of battery cell strings, and where the controller is further configured to adjust a discharging order of each individual battery cell string in the plurality of battery cell strings. In a fourth example that may include one or more of the first through third examples, the pulse power amplifier includes where the controller is further configured to adjust a charging order each individual battery cell string in the plurality of battery cell strings.

Referring now to FIG. 5, an example operating sequence for the system of FIG. 4 according to the method of FIGS. 6-8 is shown. The sequence of FIG. 5 may be provided via the system of FIG. 4 in cooperation with the method of FIGS. 6-8. The plots of FIG. 5 are time aligned. The vertical lines represent times if interest during the sequence.

The first plot from the top of FIG. 5 is a plot of a total load power that is consumed by the electric load (e.g., 470 of FIG. 4). The vertical axis represents power consumed in units of watts and the amount of power consumed increases in the direction of the vertical axis arrow. The horizontal axis represents time and time increases from the left side of the plot to the right side of the plot. Horizontal line 552 represents a first threshold level of power consumed by the electrical load. Horizontal line 550 represents a second threshold level of power consumed by the electrical load. Horizontal line 556 represents a third threshold level of power consumed by the electrical load. Horizontal line 554 represents a fourth threshold level of power consumed by the electrical load. Horizontal line 560 represents a fifth threshold level of power consumed by the electrical load. Horizontal line 558 represents a sixth threshold level of power consumed by the electrical load.

The second plot from the top of FIG. 5 is a plot of an operating state of a first pulse power amplifier control device (e.g., 410 of FIG. 4) versus time. The vertical axis represents the operating state of the first pulse power amplifier control device. The first pulse power amplifier is open (e.g., not activated) when trace 504 is at a lower level that is near the horizontal axis. The first power amplifier is closed (e.g., activated) when trace 504 is at a higher level that is near the vertical axis arrow. The horizontal axis represents time and time increases from the left side of the plot to the right side of the plot. Trace 504 represents the first pulse power amplifier control device operating state.

The third plot from the top of FIG. 5 is a plot of an operating state of a second pulse power amplifier control device (e.g., 412 of FIG. 4) versus time. The vertical axis represents the operating state of the second pulse power amplifier control device. The second pulse power amplifier is open (e.g., not activated) when trace 506 is at a lower level that is near the horizontal axis. The second power amplifier is closed (e.g., activated) when trace 506 is at a higher level that is near the vertical axis arrow. The horizontal axis represents time and time increases from the left side of the plot to the right side of the plot. Trace 506 represents the second pulse power amplifier control device operating state.

The fourth plot from the top of FIG. 5 is a plot of an operating state of a third pulse power amplifier control device (e.g., 414 of FIG. 4) versus time. The vertical axis represents the operating state of the third pulse power amplifier control device. The third pulse power amplifier is open (e.g., not activated) when trace 508 is at a lower level that is near the horizontal axis. The third power amplifier is closed (e.g., activated) when trace 508 is at a higher level that is near the vertical axis arrow. The horizontal axis represents time and time increases from the left side of the plot to the right side of the plot. Trace 508 represents the third pulse power amplifier control device operating state.

At time t10, the total amount of electric power that is consumed by the electric load (e.g., 470 of FIG. 4) is at a middle level and the power supply (not shown) provides this power to the electric load. None of the pulse power control devices are activated, so they remain open and prevent the three strings of battery cells from supplying electric power to the electric load.

At time t11, the electric power consumption rate of the electric load increases to a level that is above first threshold 552. As a result, the first pulse power amplifier control device changes state from open to closed. This allows electric power to flow from the first string of battery cells (e.g., where the first string of battery cells comprises first battery cell 420 and second battery cell 422) to the electric load. At this time, electric power does not flow from the second and third battery cell strings to the electric load. The operating states of the second and third pulse power amplifier control devices remain unchanged.

At time t12, the electric power consumption rate of the electric load increases a second time to a level that is above third threshold 556. Therefore, the second pulse power amplifier control device changes state from open to closed while the first pulse power amplifier control device remains closed and activated. This allows electric power to flow from both the first string of battery cells and the second string of battery cells (e.g., where the second string of battery cells comprises third battery cell 426, fourth battery cell 428, and fifth battery cell 430) to the electric load. At this time, electric power does not flow from the third battery cell strings to the electric load. The operating state of the third pulse power amplifier control device remains unchanged.

At time t13, the electric power consumption rate of the electric load increases a third time to a level that is above fifth threshold 560. As a result, the third pulse power amplifier control device changes state from open to closed while the first and second pulse power amplifier control devices remain closed and activated. This allows electric power to flow from all three strings of battery cells to the electric load. Thus, for increasing power consumption rates by an electric load, additional battery cell strings may be electrically coupled in parallel with an electric load so that a desired voltage and power for the electric load may be achieved. Further, as previously mentioned, the actual total number of battery cells arranged in series in each of the battery cell strings may be different as shown in FIG. 4 so that strings with progressively higher or lower power output ratings may be coupled to the electric load depending on the magnitude of the electric load.

At time t14, the electric power consumption rate of the electric load decreases to a level that is below sixth threshold 558. Therefore, the third pulse power amplifier control device changes state from closed to open. This allows electric power to stop flowing from the third string of battery cells to the electric load. Recharging of the third string of battery cells resumes (not shown). The operating states of the first and second pulse power amplifier control devices remain unchanged.

At time t15, the electric power consumption rate of the electric load decreases to a level that is below fourth threshold 554. Consequently, the second pulse power amplifier control device changes state from closed to open. This allows electric power to stop flowing from the second string of battery cells to the electric load. Recharging of the second string of battery cells resumes (not shown). The operating state of the first pulse power amplifier control device remain unchanged.

At time t16, the electric power consumption rate of the electric load decreases to a level that is below second threshold 550. As a result, the first pulse power amplifier control device changes state from closed to open. This allows electric power to stop flowing from the first string of battery cells to the electric load. Recharging of the first string of battery cells resumes (not shown).

In this way, different battery cell strings may be selectively coupled to the electric load as a function of a rate of power consumption by the electric load. This may allow power in battery cells to be allocated according to a loading priority. Further, charging may be provided to some battery cells while others are being discharged so that charging time for battery cells may be maximized.

Referring now to FIGS. 6-8, a method for operating a PPA system is shown. The method of FIGS. 6-8 may be performed by a controller that is comprised of analog circuitry, digital circuitry, a combination of analog and digital circuitry, or a microcontroller. In cases where the method of FIGS. 6-8 is performed via a controller, the method of FIGS. 6-8 may be stored as executable instructions stored in non-transitory memory of the controller. The method of FIGS. 6-8 may operate in cooperation with the system of FIG. 4. In addition, the method of FIGS. 6-8 may generate the operating sequence of FIG. 5.

At 602, method 600 optionally determines a life span measure for each battery cell string in the PPA. In one example, a life span percent measure may be a predetermined actual total number of watts of power (e.g., an expected total life span measure) minus a total cumulative number of watts of power that have been sourced and sunk by a particular battery cell string divided by the predetermined actual total number of watts of power multiplied by 100 (e.g., (predetermined value (expected life) of watts−total cumulative number of watts of power sourced or sunk by a particular battery cell string)/predetermined value*100). Battery life span measures may be determined for each battery cell string from battery sensors. Method 600 proceeds to 604.

At 604, method 600 optionally judges whether or not a battery life span measure for one string of battery cells is shorter or lower by a predetermined amount or percentage than the battery life span measures for the other battery cell strings in the PPA. A shorter or lower life span measure in this context means that a greater percentage of a particular battery cell string's life span has been consumed. Further, method 600 may judge whether or not a battery cell string is degraded (e.g., the battery cell string may not store a desired amount of charge). If method 600 judges that a battery life span measure for one string of battery cells is shorter by a predetermined amount or percentage than the battery life span measures for the other battery cell strings in the PPA or degradation of a battery cell string is determined, the answer is yes and method 600 proceeds to 605. Otherwise, the answer is no and method 600 proceeds to 606.

At 605, adjusts an order in which battery cell strings are to be coupled to the electric load when conditions for coupling the battery cell strings to the electric load are met. In one example, the order may be adjusted so that the battery cell string with the longest or highest life span measure is selected to be the first predetermined battery cell string to be electrically coupled to the electric load when conditions are met for pulse power boosting. The second predetermined battery cell string to be electrically coupled to the electric load is the battery cell string with the next longest or next highest life span measure, and so on. In this way, battery cell strings with shorter life span measures may be electrically coupled to the electric load less frequently so as to extend their life span.

In addition, if a battery cell string is determined to be degraded, method 600 may remove the degraded battery cell string from the list of battery cell strings that may be electrically coupled to the load. Further, method 600 may communicate an inability to provide a full power boost capability to the electric load for present and future load increasing events. In some examples, method 600 may communicate a power boost capacity to the electric load so that the electric load may compensate. In this way, degraded battery cell strings may be separated from non-degraded battery cell strings and the electric load. Method 600 proceeds to 608.

At 606, method 600 may apply a predetermined order to the order in which battery cell strings are electrically coupled to the electric load when conditions are met to couple battery cell strings to the electric load. In one example, the predetermined order may be a first battery cell string is a first predetermined battery cell string, followed by a second battery cell string that is the second predetermined battery cell string, followed by a third battery cell string that is the third predetermined battery cell string. In this example, the first, second, and third predetermined battery cell strings are electrically coupled to the electric load. The predetermined order in which battery cell strings are coupled to the electric load may be such that battery cell strings with higher watt ratings are coupled to the electric load before battery cell strings with lower watt ratings, or vise-versa depending on objectives. Method 600 proceeds to 608.

At 608, method 600 judges whether or not the electrical load has been commanded off, if the electric load is in a power-up mode, and/or if degradation of the nickel/zinc battery cells is present. Method 600 may receive this information from the electric load via communication link and via the controller itself performing diagnostics on the nickel/zinc battery cells. If method 600 judges that electrical load has been commanded off, if the electric load is in a power-up mode where DC bus voltage may be low, and/or if degradation of the nickel/zinc battery cell string is present, the answer is yes and method 600 proceeds to 609. Otherwise, the answer is no and method 600 proceeds to 610.

At 609, method 600 opens the pulse power amplifier control devices. Opening the pulse power amplifier control devices electrically decouples the battery cell strings from the electric load so that the power flow from the battery cell strings ceases. Additionally, method 300 closes the charger control devices so that charging of the battery cell strings resumes while the battery cells are not supplying power to the electric load. This action helps to ensure that the battery cells are recharged for subsequent loading. Method 600 proceeds to exit.

At 610, method 600 judges whether or not a load bus voltage (e.g., a voltage at a positive power terminal of an electric load or a voltage of a bus that supplies electric power to an electric load) is less than a first threshold voltage, or alternatively, if load bus electric power consumption (e.g., a rate of electric power consumption by an electric load that is fed power via a bus) is greater than a first threshold power consumption rate. If so, the answer is yes and method 600 proceeds to 612. If not, the answer is no and method 600 proceeds to 614.

As previously mentioned, some electric loads (e.g., GPUs, combinations of GPUs and CPUs, etc.) may have a capacity to indicate that a computational load is expected to increase before the computational load actual increases. If an electric load with such capacity is present, method 600 may receive the preemptive power consumption information from the electric load before the load bus voltage drops or the load bus power consumption rate increases. This allows the controller (e.g., 470 of FIG. 4) to electrically couple the nickel/zinc battery cells to the electric loads before, or simultaneously with, the time that the electrical load is expected to increase. Therefore, if method 600 receives such information at 610 before a voltage drop or power consumption increase, method 600 may proceed to 612.

At 612, method 600 activates a first predetermined battery cell string by closing a pulse power amplifier control device that is associated with the first predetermined battery cell string. For example, if the first predetermined battery cell string to be coupled to the electric load is the battery cell string that includes first battery cell 420 in FIG. 4, first pulse power amplifier control device 410 is closed because it is associated with the first predetermined battery cell string. Method 600 closes the first pulse power amplifier control device that is associated with the first predetermined battery cell string, or alternatively, operates the pulse power amplifier control device in a linear mode such that the pulse power amplifier operates as a voltage controlled variable resistor. Additionally, method 600 opens the charger control device that is associated with the first predetermined battery cell string so that charging of the battery cells in the first predetermined battery cell string ceases. Method 600 proceeds to 614.

At 614, method 600 judges whether or not a load bus voltage (e.g., a voltage at a positive power terminal of an electric load or a voltage of a bus that supplies electric power to an electric load) is greater than a second threshold voltage, or alternatively, if load bus electric power consumption rate (e.g., a rate of electric power consumption by an electric load that is fed power via a bus) is less than a second threshold power consumption rate. The second threshold voltage is greater than the first threshold voltage and the second threshold power consumption rate is less than the first threshold power consumption rate. If method 300 judges that the load bus voltage is greater than a second threshold voltage or that the load bus electric power consumption rate is less than a second threshold power consumption rate, the answer is yes and method 600 proceeds to 650. If not, the answer is no and method 600 proceeds to 616.

At 650, method 600 opens the pulse power amplifier control device that is associated with the first predetermined battery cell string. Opening the pulse power amplifier control device electrically decouples the battery cells from the electric load so that the power flow from the battery cells ceases. Additionally, method 600 closes the charger control device that is associated with the first predetermined battery cell string so that charging of the battery cells in the first predetermined battery cell string resumes. This action helps to ensure that the battery cells in the first predetermined battery cell string are recharged for subsequent loading. Method 600 proceeds to 616.

At 616, method 600 judges whether or not a load bus voltage (e.g., a voltage at a positive power terminal of an electric load or a voltage of a bus that supplies electric power to an electric load) is less than a third threshold voltage, or alternatively, if load bus electric power consumption (e.g., a rate of electric power consumption by an electric load that is fed power via a bus) is greater than a third threshold power consumption rate. If so, the answer is yes and method 600 proceeds to 618. If not, the answer is no and method 600 proceeds to 622.

Additionally, if an electric load with such capacity to anticipate and communicate upcoming increasing pulse loads is present, method 600 may receive the preemptive power consumption information from the electric load before the load bus voltage drops or the load bus power consumption rate increases. This allows the controller (e.g., 470 of FIG. 4) to electrically couple the battery cells to the electric loads before, or simultaneously with, the time that the electrical load is expected to increase. Therefore, if method 600 receives such information at 616 before a voltage drop or power consumption increase, method 600 may proceed to 618.

At 618, method 600 activates a second predetermined battery cell string by closing a pulse power amplifier control device that is associated with the second predetermined battery cell string. Method 600 closes the second pulse power amplifier control device that is associated with the second predetermined battery cell string, or alternatively, operates the pulse power amplifier control device in a linear mode such that the pulse power amplifier operates as a voltage controlled variable resistor. Additionally, method 600 opens the charger control device that is associated with the second predetermined battery cell string so that charging of the battery cells in the second predetermined battery cell string ceases. Method 600 proceeds to 620.

At 620, method 600 judges whether or not a load bus voltage (e.g., a voltage at a positive power terminal of an electric load or a voltage of a bus that supplies electric power to an electric load) is greater than a fourth threshold voltage, or alternatively, if load bus electric power consumption rate (e.g., a rate of electric power consumption by an electric load that is fed power via a bus) is less than a fourth threshold power consumption rate. The fourth threshold voltage is greater than the third threshold voltage and the fourth threshold power consumption rate is less than the third threshold power consumption rate. If method 600 judges that the load bus voltage is greater than the fourth threshold voltage or that the load bus electric power consumption rate is less than the fourth threshold power consumption rate, the answer is yes and method 600 proceeds to 651. If not, the answer is no and method 600 proceeds to 622.

At 651, method 600 opens the pulse power amplifier control device that is associated with the second predetermined battery cell string. Opening the pulse power amplifier control device electrically decouples the battery cells in the second predetermined battery cell string from the electric load so that the power flow from the battery cells ceases. Additionally, method 600 closes the charger control device that is associated with the second predetermined battery cell string so that charging of the battery cells in the second predetermined battery cell string resumes. This action helps to ensure that the battery cells in the second predetermined battery cell string are recharged for subsequent loading. Method 600 proceeds to 624.

At 622, method 600 judges whether or not a load bus voltage (e.g., a voltage at a positive power terminal of an electric load or a voltage of a bus that supplies electric power to an electric load) is less than a fifth threshold voltage, or alternatively, if load bus electric power consumption (e.g., a rate of electric power consumption by an electric load that is fed power via a bus) is greater than a fifth threshold power consumption rate. If so, the answer is yes and method 600 proceeds to 624. If not, the answer is no and method 600 proceeds to 628.

Additionally, if an electric load with such capacity to anticipate and communicate upcoming increasing pulse loads is present, method 600 may receive the preemptive power consumption information from the electric load before the load bus voltage drops or the load bus power consumption rate increases. This allows the controller (e.g., 470 of FIG. 4) to electrically couple the battery cells to the electric loads before, or simultaneously with, the time that the electrical load is expected to increase. Therefore, if method 600 receives such information at 622 before a voltage drop or power consumption increase, method 600 may proceed to 624.

At 624, method 600 activates a third predetermined battery cell string by closing a pulse power amplifier control device that is associated with the third predetermined battery cell string. Method 600 closes the third pulse power amplifier control device that is associated with the third predetermined battery cell string, or alternatively, operates the pulse power amplifier control device in a linear mode such that the pulse power amplifier operates as a voltage controlled variable resistor. Additionally, method 600 opens the charger control device that is associated with the third predetermined battery cell string so that charging of the battery cells in the third predetermined battery cell string ceases. Method 600 proceeds to 628.

At 628, method 600 judges whether or not a load bus voltage (e.g., a voltage at a positive power terminal of an electric load or a voltage of a bus that supplies electric power to an electric load) is greater than a sixth threshold voltage, or alternatively, if load bus electric power consumption rate (e.g., a rate of electric power consumption by an electric load that is fed power via a bus) is less than a sixth threshold power consumption rate. The sixth threshold voltage is greater than the fifth threshold voltage and the sixth threshold power consumption rate is less than the fifth threshold power consumption rate. If method 600 judges that the load bus voltage is greater than the sixth threshold voltage or that the load bus electric power consumption rate is less than the sixth threshold power consumption rate, the answer is yes and method 600 proceeds to 652. If not, the answer is no and method 600 proceeds to exit.

At 652, method 600 opens the pulse power amplifier control device that is associated with the third predetermined battery cell string. Opening the pulse power amplifier control device electrically decouples the battery cells in the third predetermined battery cell string from the electric load so that the power flow from the battery cells ceases. Additionally, method 600 closes the charger control device that is associated with the third predetermined battery cell string so that charging of the battery cells in the third predetermined battery cell string resumes. This action helps to ensure that the battery cells in the third predetermined battery cell string are recharged for subsequent loading. Method 600 proceeds to exit.

Thus, the method of FIGS. 6-8 may selectively electrically couple separate and distinct nickel/zinc battery cell strings to an electric load that exhibits pulse power consumption. The approach may reduce a possibility of a DC bus voltage falling below levels specified for a particular electric load, such as a GPU. Further, the approach may extend battery cell string life spans by rotating battery cell strings that are electrically coupled to an electric load.

In the method of FIGS. 6-8, predetermined battery cell strings one through N, where N is an integer value, may be electrically coupled to an electric load beginning with a first predetermined battery cell string and ending with the Nth battery cell string. Further, battery cell strings that are assigned to be the first predetermined battery cell string to the Nth battery cell string may be ordered according to battery life span and/or a predetermined order. The method of FIGS. 6-8 also provides for electrically decoupling predetermined battery cell strings beginning with the most recent battery cell string to be electrically coupled to the electrical load and ending with the first predetermined battery cell string.

Thus, the method of FIGS. 6-8 provides for a method for operating a pulse power amplifier, comprising: flowing electric current through a pulse power control device that is directly electrically coupled to a battery cell string in response to a voltage of an electric load being less than a first threshold voltage or a power consumption rate of the electric load exceeding a first threshold power consumption rate; and ceasing electric current flow through the pulse power control device in response to the voltage of the electric load being greater than a second voltage or the power consumption rate of the electric load being less than a second threshold power consumption rate. In a first example, the method further comprises opening a charger control device to prevent charging of battery cells in the battery cell string via a charger in response to permitting electric current flow through the pulse power control device. In a second example that may include the first example, the method further comprises communicating inability to provide pulse power amplification at a future time to the electric load. In a third example that may include one or both of the first and second examples, the method further comprises communicating inability to provide pulse power amplification at a present time to the electric load. In a fourth example that may include one or more of the first through third examples, the method further comprises flowing electric current through a second pulse power control device that is directly electrically coupled to a second battery cell string in response to the voltage of the electric load being less than a third threshold voltage or the power consumption rate of the electric load exceeding a third threshold power consumption rate, where the third threshold voltage is less than the first threshold voltage and the first threshold power consumption rate is less than the third threshold power consumption rate. In a fifth example that may include one or more of the first through fourth examples, the method further comprises adjusting an order in which the battery cell string and the second battery cell string are discharged.

In another representation, the method of FIGS. 6-8 also provides for a method for operating a pulse power amplifier, comprising: flowing electric current through a first pulse power control device that is electrically coupled to a first battery cell string in response to a voltage of an electric load being less than a first threshold voltage or a power consumption rate of the electric load exceeding a first threshold power consumption rate; and flowing electric current through a second pulse power control device that is electrically coupled to a second battery cell string in response to the voltage of the electric load being less than a second threshold voltage or the power consumption rate of the electric load exceeding a second threshold power consumption rate.

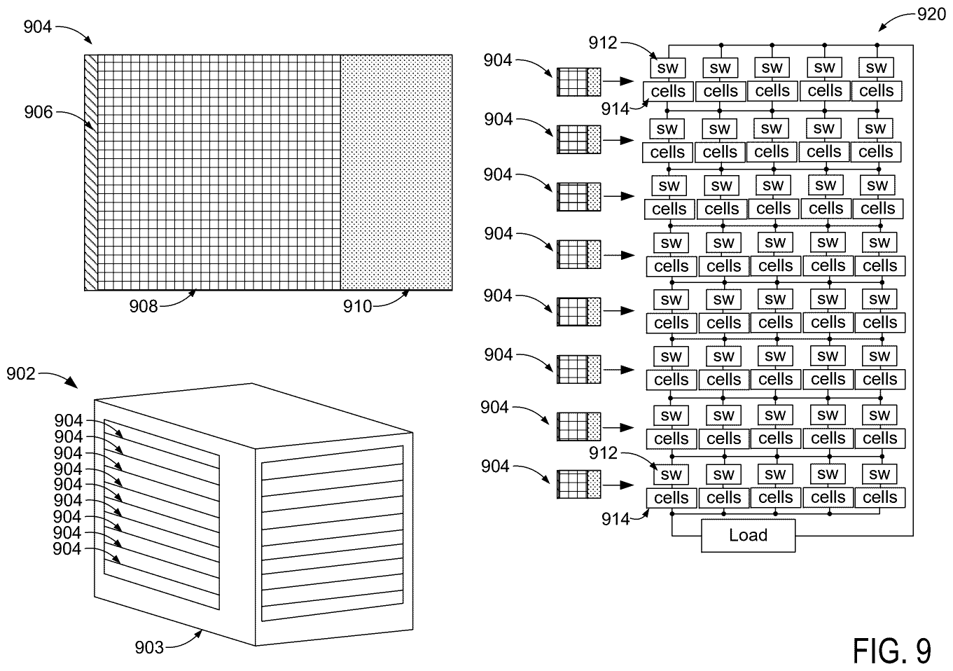

Referring now to FIG. 9, a PPA assembly 902 is shown. In this example, PPA assembly 902 includes a rack 903 and rack 903 supports PPA trays 904. The PPA trays 904 include a fan section 906 that includes fans (not shown) to cool battery cells 914 that are included in battery cell section 908. The battery cells 908 may be electrically coupled to other battery cells via switches 912 that are included in switch section 910. The PPA trays 904 may be electrically coupled in series and in parallel as indicated at 920. The PPA trays 904 may be selectively electrically coupled to a PSU to provide compensation for brief increases in GPU electric power consumption.

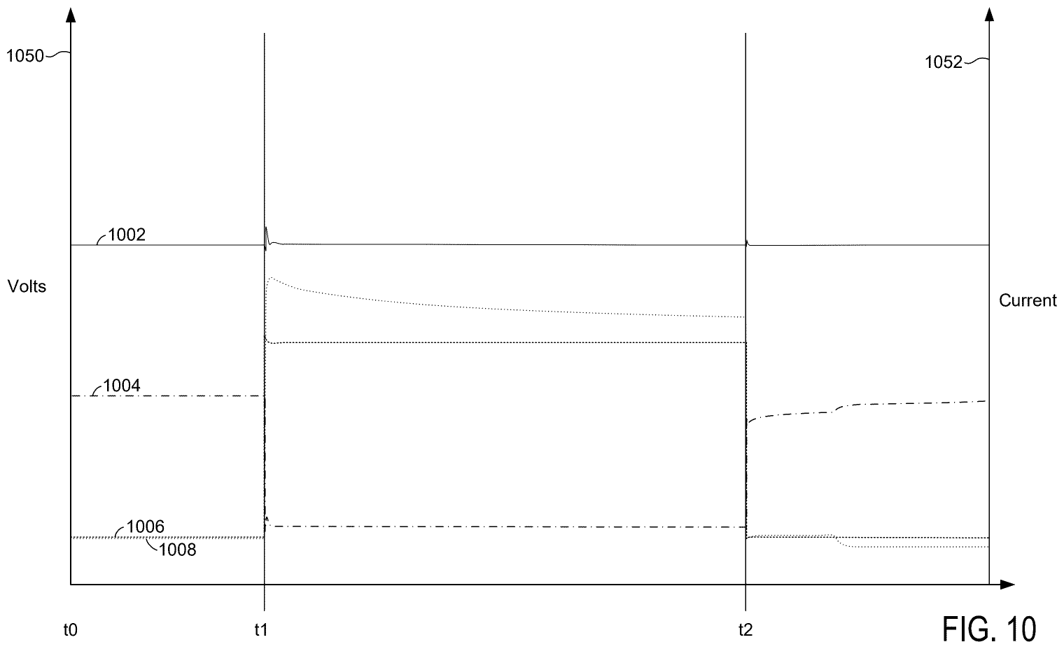

Turning now to FIG. 10, an example sequence where a PPA is applied to compensate for a 50 millisecond increase in GPU load is shown. FIG. 10 includes a vertical right axis 1050 and a vertical left axis 1052. Vertical left axis 1052 represents voltage and voltage level increases in the direction of the vertical left axis arrow.

Solid line trace 1002 represents PSU output voltage and dashed dot line 1004 represents battery pack voltage (voltage output of a PPA assembly). Dashed line 1006 represents pulse load current (current consumed by the GPUs). Dotted line 1008 represents battery pack current (output current of the PPA assembly).

The sequence begins at time t0 and the load pulse begins at time t1. The load pulse ends at time t2. The PPA is electrically coupled to the PSU near time t1 and it is decoupled from the PSU near time t2. This allows the PSU output voltage to remain nearly constant in the presence of a GPU load increase. During the load pulse, the battery pack current is greater than the pulse load current. The PSU current reduces during the load pulse to regulate and maintain the bus voltage. The battery pack begins to recharge via a charger after time t2.

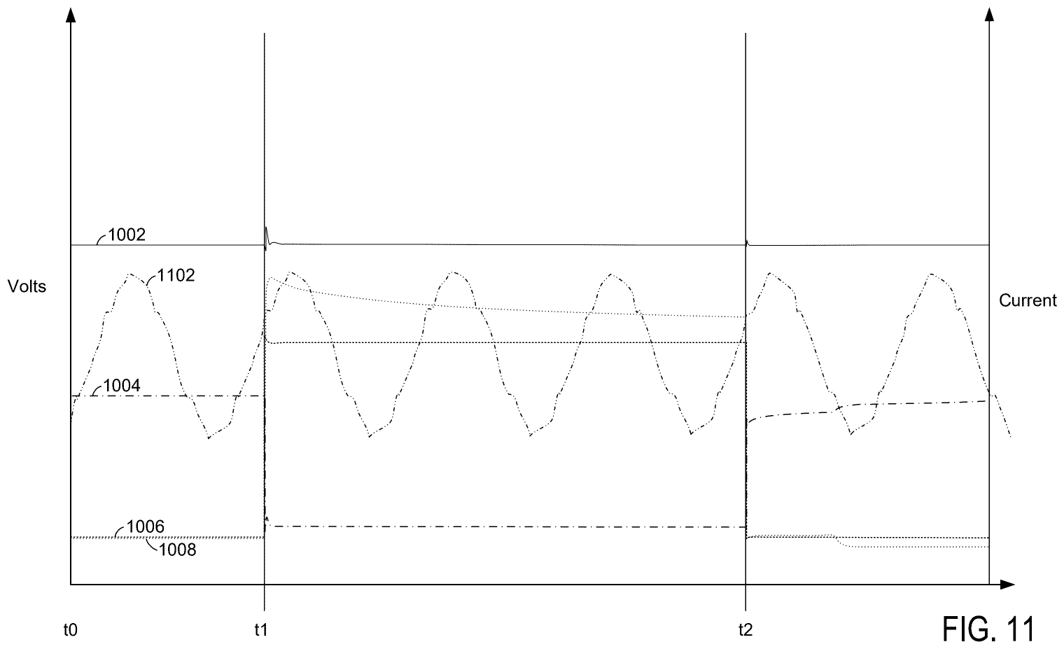

Referring now to FIG. 11, the sequence shown in FIG. 10 is shown again, except in this plot, the AC input current to the PSU is shown. The AC input current to the PSU is indicated by dash-dot-dot line 1102. Notice at times t1 and t2 that there is no change in the AC input current waveform. This indicates that the PSU does not load the AC line when the load pulse is applied.

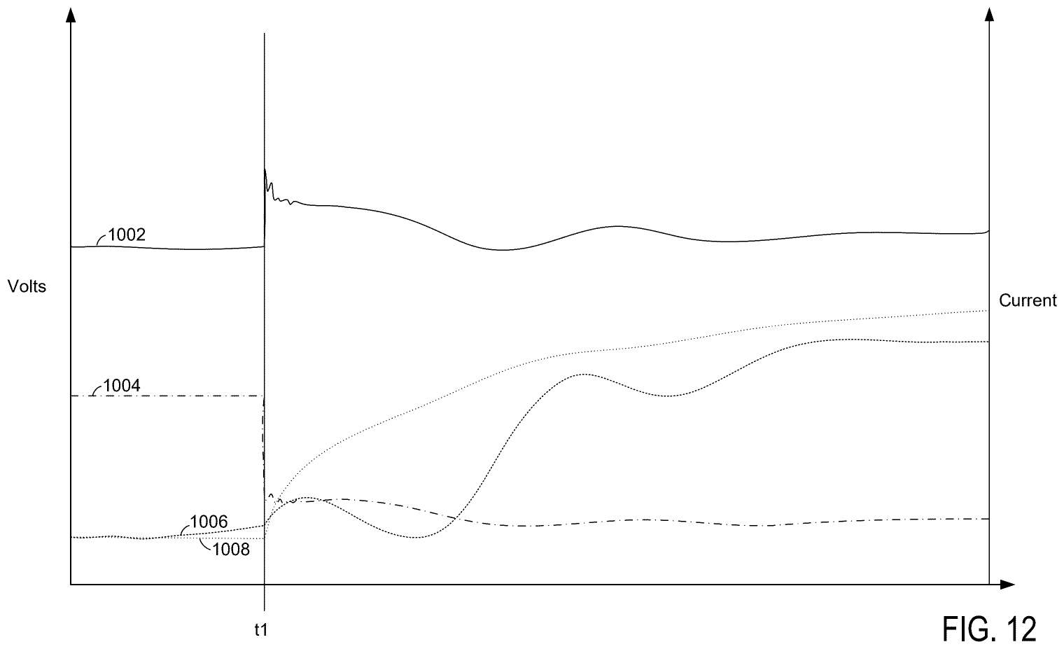

Referring now to FIG. 12, the sequence of shown in FIG. 10 is shown again, except FIG. 12 zooms in on the plot of FIG. 10 near time t1. This plot indicates that the battery pack responds to the change in GPU load in 50 micro-seconds in this example.

While various embodiments have been described above, it may be understood that they have been presented by way of example, and not constraining nor restriction. It will be appreciated that the configurations and routines disclosed herein are exemplary in nature, and that these specific examples are not to be considered in a constraining sense, because numerous variations are possible. For example, the above technology may be applied to other types of battery cells and when supplying electric power to electric loads other than or in addition to GPU loads. The subject matter of the present disclosure includes all novel and non-obvious combinations and sub-combinations of the various systems and configurations, and other features, functions, and/or properties disclosed herein. It will be apparent to persons skilled in the relevant arts that the disclosed subject matter may be embodied in other specific forms without departing from the spirit of the subject matter.

Note that the example control and estimation routines included herein may be used with various power system configurations. In some examples, the control methods and routines disclosed herein may be stored as executable instructions in non-transitory memory and may be carried out by the control system including the controller in combination with the various sensors, actuators, and other transmission and/or vehicle hardware. Further, portions of the methods may be physical actions taken in the real world to change a state of a device. Thus, the described actions, operations and/or functions may graphically represent code to be programmed into non-transitory memory of the computer readable storage medium in the vehicle and/or transmission control system. The specific routines described herein may represent one or more of any number of processing strategies such as event-driven, interrupt-driven, multi-tasking, multi-threading, and the like. As such, various actions, operations, and/or functions illustrated may be performed in the sequence illustrated, in parallel, or in some cases omitted. Likewise, the order of processing is not necessarily required to achieve the features and advantages of the examples described herein, but is provided for ease of illustration and description. One or more of the illustrated actions, operations and/or functions may be repeatedly performed depending on the particular strategy being used. One or more of the method steps described herein may be omitted if desired.

The following claims particularly point out certain combinations and sub-combinations regarded as novel and non-obvious. These claims may refer to “an” element or “a first” element or the equivalent thereof. Such claims may be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

The following claims particularly point out certain combinations and sub-combinations regarded as novel and non-obvious. These claims may refer to “an” element or “a first” element or the equivalent thereof. Such claims may be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A pulse power amplifier, comprising:
a battery cell string;
a pulse power amplifier control device electrically coupled to the battery cell string; and
a controller configured to control electric power flow through the pulse power amplifier control device in response to a voltage of an electric load or an amount of electric power consumed by the electric load.

2. The pulse power amplifier of claim 1, where pulse power amplifier control device is a transistor, diode, and/or other solid state switching device.

3. The pulse power amplifier of claim 1, where the battery cell string includes a first battery cell and a second battery cell that are nickel/zinc battery cells and that include a negative zinc electrode and a positive nickel electrode.

4. The pulse power amplifier of claim 1, where the controller is configured to close the pulse power amplifier control device in response to the voltage being less than a threshold voltage and/or the amount of electric power consumed by the electric load exceeding a threshold amount of power.

5. The pulse power amplifier of claim 1, further comprising a charger and a charger control device, where the charger is directly electrically coupled to the charger control device, and where the charger control device is directly electrically coupled to the battery cell string.

6. The pulse power amplifier of claim 1, further comprising a power supply arranged in parallel with the electric load.

7. The pulse power amplifier of claim 1, further comprising a second battery cell string and a second pulse power amplifier control device arranged in parallel with the battery cell string and the pulse power amplifier control device.

8. The pulse power amplifier of claim 7, where the battery cell string includes a first actual total number of battery cells arranged in series, where the second battery cell string includes a second actual total number of battery cells arranged in series, and where the second actual total number of battery cells is different than the first actual total number of battery cells.

9. The pulse power amplifier of claim 8, further comprising a charger and a first charger control device and a second charger control device, where the first charger control device is directly electrically coupled to the battery cell string, and where the second charger control device is directly electrically coupled to the second battery cell string.

10. A method for operating a pulse power amplifier, comprising:
flowing electric current through a pulse power control device that is directly electrically coupled to a battery cell string in response to a voltage of an electric load being less than a first threshold voltage or a power consumption rate of the electric load exceeding a first threshold power consumption rate; and
ceasing electric current flow through the pulse power control device in response to the voltage of the electric load being greater than a second voltage or the power consumption rate of the electric load being less than a second threshold power consumption rate.

11. The method of claim 10, further comprising opening a charger control device to prevent charging of battery cells in the battery cell string via a charger in response to permitting electric current flow through the pulse power control device.

12. The method of claim 10, further comprising communicating inability to provide pulse power amplification at a future time to the electric load.

13. The method of claim 12, further comprising communicating inability to provide pulse power amplification at a present time to the electric load.

14. The method of claim 10, further comprising flowing electric current through a second pulse power control device that is directly electrically coupled to a second battery cell string in response to the voltage of the electric load being less than a third threshold voltage or the power consumption rate of the electric load exceeding a third threshold power consumption rate, where the third threshold voltage is less than the first threshold voltage and the first threshold power consumption rate is less than the third threshold power consumption rate.

15. The method of claim 14, further comprising adjusting an order in which the battery cell string and the second battery cell string are discharged.

16. A pulse power amplifier, comprising:
a battery cell string;
a pulse power amplifier control device electrically coupled to the battery cell string; and
a controller configured to control electric power flow through the pulse power amplifier control device and control electric power flow through a charger control device in response to a voltage of an electric load and/or an amount of electric power consumed by the electric load.

17. The pulse power amplifier of claim 16, further comprising a communications link between a charger and the controller.

18. The pulse power amplifier of claim 16, further comprising a communications link between the controller and the electric load.

19. The pulse power amplifier of claim 16, where the electric load is a graphics processing unit, where the battery cell string includes a first battery cell and a second battery cell, where the battery cell string is included in a plurality of battery cell strings, and where the controller is further configured to adjust a discharging order of each individual battery cell string in the plurality of battery cell strings.

20. The pulse power amplifier of claim 19, where the controller is further configured to adjust a charging order each individual battery cell string in the plurality of battery cell strings.
